(19) United States
(12) Patent Application Publication
(10) Pub. No.: US 2017/0358780 A1
(43) Pub. Date: Dec. 14, 2017

(54) OLED DEVICE WITH OPTICAL RESONANCE LAYER AND FABRICATING METHOD THEREOF, AND DISPLAY DEVICE

(71) Applicants: BEIJING VISIONOX TECHNOLOGY CO., LTD., Beijing (CN); KUNSHAN NEW FLAT PANEL DISPLAY TECHNOLOGY CENTER CO., LTD., KunShan City, Jiangsu (CN)

(72) Inventors: Mengzhen LI, Beijing (CN); Song LIU, Beijing (CN); Song GAO, Beijing (CN); Wei AO, Kunshan (CN); Siran ZHOU, Kunshan (CN)

(73) Assignees: BEIJING VISIONOX TECHNOLOGY CO., LTD., Beijing (CN); KUNSHAN NEW FLAT PANEL DISPLAY TECHNOLOGY CENTER CO., LTD., KunShan City, Jiangsu (CN)

(21) Appl. No.: 15/541,326

(22) PCT Filed: Dec. 14, 2015
(86) PCT No.: PCT/CN2015/097230

§ 371 Date: Jun. 30, 2017

(30) Foreign Application Priority Data
Dec. 31, 2014 (CN) 201410846639.1

(51) Int. Cl. H01L 51/52; H01L 27/32; H01L 51/56

(52) U.S. Cl. CPC H01L 51/5275; H01L 27/3213; H01L 27/322; H01L 51/56

(57) ABSTRACT

The present invention discloses an OLED device with an optical resonance layer and fabricating method thereof, and a display device. The OLED device comprises: a white light OLED and a color filter film, so as to form an R sub-pixel, a G sub-pixel, a B sub-pixel and a W sub-pixel, wherein an optical resonance layer is disposed at least in a region corresponding to the G sub-pixel between the white light OLED and the color filter film. By providing the optical resonance layer, the OLED device with an optical resonance layer of the present invention can filter monochromatic lights with good chromaticity and high efficiency, even by using a color filter film with a low color gamut, and specially, the problem of the low display quality in white light OLED+CF technology at present is solved. In addition, the OLED device of the present invention also greatly reduces the power consumption. Moreover, there is no need to use a fine metal mask (FMM), thereby reducing the processing cost.

### TECHNICAL FIELD

The present invention relates to the technical field of OLED display, and more particularly, to an OLED device with an optical resonance layer and fabricating method thereof, and a display device comprising the OLED device.

### BACKGROUND ART

As the progress of science and technology, LCD (liquid crystal display) has gradually replaced the conventional bulky CRT (cathode ray tube), and has been widely applied to monitors, laptops, flat panel TVs, digital cameras and other electronic products, because of its advantages of small volume and light weight.

LCD needs LED (Light Emitting Diode) as the backlight light source. OLED (Organic Light Emitting Diode) display does not need a backlight module, and has the advantage of no visual angle limitation, so it is more suitable for the thin display, and has the tendency to replace the conventional CRT and LCD.

OLED displays have forms such as RGB displays and white light OLED+CF (Color Filter, Color Filter membrane), wherein the white light OLED+CF is a display technique that can realize large size and high resolution. However, white light will lose most of the light after passing through the CF, so the power consumption of the display screen is very high. Moreover, the color gamut of CF is low, and especially the color saturation of the green light is low, and the display effect is not good. How to improve the utilization rate of light to reduce the power consumption is a problem that urgently needs to be solved in white light OLED+CF technology.

In order to solve that problem, in the prior art, there is a solution of increasing white light pixels, that is, RGBW four pixels are adopted to reduce the power consumption, and there is also a solution that uses quantum dots light conversion layer to improve the conversion efficiency. However, those solutions are not ideal. In the prior art, there is also a technical solution that uses a uniform light scattering layer, but, in that solution, the extraction effect of part of light spectral band is not obvious. There is also another solution where different light resonance layers are used for R/G/B sub-pixels, but the process of the technical solution is very difficult and of high cost, and difficult to achieve the commercial application.

### SUMMARY

The technical problems to be solved by the present invention are to provide an OLED device with an optical resonance layer of high light efficiency, wide color gamut and low cost, and fabricating method thereof, and a display device comprising the OLED device.

To solve the above technical problems, the present invention provides an OLED device with an optical resonance layer, comprising: a white light OLED and a color filter film, so as to form an R sub-pixel, a G sub-pixel, a B sub-pixel and a W sub-pixel, wherein an optical resonance layer is disposed at least in a region corresponding to the G sub-pixel between the white light OLED and the color filter film.

Optionally, the optical resonance layer is a composite medium layer which at least comprises a first medium layer and a second medium layer, wherein the first medium layer is close to the color filter film, the second medium layer is located on the first medium layer, and a refractive index of the first medium layer is higher than that of the second medium layer.

Optionally, the refractive index of the second medium layer is 1-1.6.

Optionally, the refractive index of the first medium layer is at least 0.2 higher than the refractive index of the second medium layer.

Optionally, a thickness of the optical resonance layer enables optical paths from a reflection electrode to each of interfaces of the medium layers to meet an interference enhancement formula: L=(2n+1)λ/4, wherein: L is the optical path from the reflection electrode to one of the interfaces of the medium layers, n is a natural number, and λ is a central wavelength of filtered light.

Optionally, a thickness of the first medium layer is 10-150 nm, and a thickness of the second medium layer is 0-300 nm.

Optionally, the optical resonance layer is disposed in one selected from, or in any combination of regions corresponding to the R sub-pixel, the B sub-pixel and the W sub-pixel between the white light OLED and the color filter film.

The present invention also provides a display device comprising the above OLED device with an optical resonance layer.

The present invention also provides a method for fabricating an OLED device with an optical resonance layer, comprising the following steps:

cleaning a substrate, and fabricating a TFT array on the substrate,

fabricating a color filter film,

fabricating a flat layer on the color filter film,
fabricating the optical resonance layer on the flat layer of the corresponding to the region of a G sub-pixel

fabricating a transparent electrode on the optical resonance layer,

fabricating a white light OLED device, and

packaging to complete the fabricating of the display device.

Optionally, the step of fabricating the optical resonance layer in a region corresponding to a G sub-pixel comprises:

fabricating a first medium layer with a thickness of 10-150 nm, and

fabricating a second medium layer with a thickness of 0-300 nm on the first medium layer.

The advantage of the present invention is that:

By providing the optical resonance layer, the OLED device with an optical resonance layer provided by the present invention can filter monochromatic lights with good chromaticity and high efficiency, even by using a color filter film with a low color gamut, and specially, the problem of the low display quality in white light OLED+CF technology at present is solved. In addition, the OLED device provided by the present invention also greatly reduces the power consumption. Moreover, there is no need to use a fine metal mask (FMM), thereby reducing the processing cost.

### BRIEF DESCRIPTION OF THE DRAWINGS

FIG. 1 is a structural schematic diagram of the first embodiment of an OLED device with an optical resonance layer according to the present invention.

FIG. 2 is a structural schematic diagram of the second embodiment of an OLED device with an optical resonance layer according to the present invention.

FIG. 3 is a structural schematic diagram of the third embodiment of an OLED device with an optical resonance layer according to the present invention.

In the drawings, 1 indicates a reflection electrode, 2 indicates a white light OLED, 3 indicates a transparent electrode, 4 indicates an optical resonance layer, 41 indicates a second medium layer, 42 indicates a first medium layer, 4′ indicates a filling layer, 5 indicates a flat layer, and 6 indicates a color filter film.

### DETAILED DESCRIPTION OF THE PREFERRED EMBODIMENTS

In the following, the present invention will be described in further detail with reference to the drawings and the detailed embodiments, in order to enable those skilled in the art to better understand and implement the present invention, but the present invention is not limited to the illustrated embodiments.

The OLED device with an optical resonance layer according to the present invention comprises a white light OLED and a color filter film (CF), so as to form an R sub-pixel (red sub-pixel), a G sub-pixel (green sub-pixel), a B sub-pixel (blue sub-pixel) and a W sub-pixel (white sub-pixel), and an optical resonance layer is disposed in the region corresponding to the G sub-pixel between the white light OLED and the CF.

The optical resonance layer may also be a composite medium layer comprising a first medium layer and a second medium layer, wherein the first medium layer is close to the color filter film, the second medium layer is located on the first medium layer, and a refractive index of the first medium layer is higher than that of the second medium layer.

Preferably, the refractive index of the second medium layer is 1-1.6, and the refractive index of the first medium layer is at least 0.2 higher than the refractive index of the second medium layer.

The thickness of the optical resonance layer enables optical paths from a reflection electrode to each of interfaces of the medium layers to meet an interference enhancement formula: L=(2n+1)λ/4, wherein: L is the optical path from the reflection electrode to one of the interfaces of the medium layers, n is a natural number, and λ is a central wavelength of filtered light. Generally, a thickness of the first medium layer is 10-150 nm, and a thickness of the second medium layer is 0-300 nm. When the thickness of the second medium layer is 0, that denotes that the optical resonance layer is a single-layer structure, that is, the optical resonance layer only consists of the first medium layer. At this time, the refractive index of the first medium layer is higher than the refractive index of the transparent electrode of the white light OLED that is in contact with the first medium layer.

In addition, an optical resonance layer may also be arranged in the regions corresponding to the R sub-pixel, the B sub-pixel and the W sub-pixel between the white light OLED and the CF. That is, besides the G sub-pixel, optical resonance layers may also be arranged for other color sub-pixels according to need. The optical resonance layer may be arranged in one or in any two selected from the regions corresponding to the R sub-pixel, the B sub-pixel and the W sub-pixel. Of course, the optical resonance layers may also be arranged in three regions. The optical resonance layers of other color sub-pixels may be the same as that of the G sub-pixel, and may be different.

A method for fabricating an OLED device with an optical resonance layer according to the present invention comprises the following steps:

cleaning a substrate, and fabricating a TFT array on the substrate,

fabricating a color filter film,

fabricating a flat layer on the color filter film,

fabricating the optical resonance layer on the flat layer of the corresponding to the region of a G sub-pixel,

fabricating a transparent electrode on the optical resonance layer,

fabricating a white light OLED device, and

packaging to complete the fabricating of the display device.

Optionally, the step of fabricating the optical resonance layer in a region corresponding to a G sub-pixel comprises:

fabricating a first medium layer with a thickness of 10-150 nm, and

fabricating a second medium layer with a thickness of 0-300 nm on the first medium layer.

The present invention will be explained by the detailed description of the embodiments.

### The First Embodiment

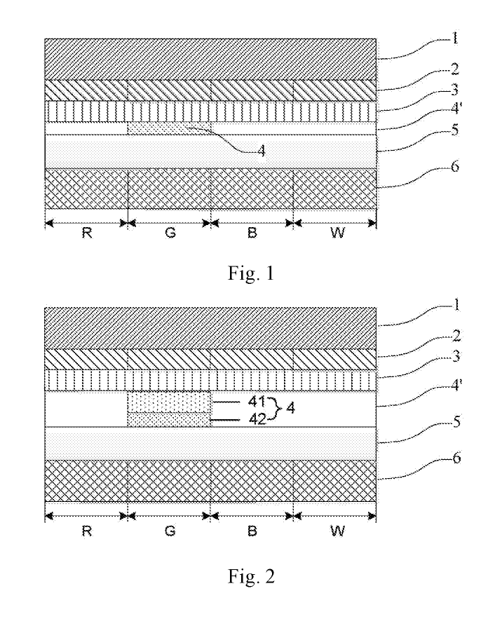

As shown in FIG. 1, an OLED device with an optical resonance layer according to this embodiment comprises: a substrate, a TFT array (not shown in the figure) disposed on the substrate, and a color filter film 6 on the TFT array, wherein the color filter film 6 is divided into four colors of R, B and W, so as to filter the white light emitted by the white light OLED, to form an R sub-pixel, a G sub-pixel, a B sub-pixel and a W sub-pixel. The R sub-pixel, the G sub-pixel, the B sub-pixel and the W sub-pixel can emit lights with different intensities according to need, and the lights emitted by the R sub-pixel, the G sub-pixel, the B sub-pixel and the W sub-pixel are mixed to obtain the required color, so as to realize color display. A plurality of the OLED devices are arranged according to a certain rule (such as an array), and cooperate with a casing and other components to form the display device of the present invention

In the embodiment shown in FIG. 1, a flat layer 5 is arranged on the color filter film 6, and an optical resonance layer 4 is arranged on the flat layer 5, wherein the optical resonance layer 4 exists only in the region corresponding to the G sub-pixel. In this embodiment, the optical resonance layer 4 is a single-layer medium structure, that is, it has only a first medium layer. A transparent electrode 3 is formed on the optical resonance layer 4, and the refractive index of the optical resonance layer 4 is higher than the refractive index of the transparent electrode 3. A white light OLED 2 and a reflection electrode 1 are arranged on the transparent electrode 3, and an OLED device is formed by packaging. A filling layer 4′ is provided in a region without the optical resonance layer to fill the gap. The material of the filling layer 4′ may be the same as that of the flat layer 5.

The method for fabricating the OLED device in the embodiment is as follows:
1. cleaning the substrate, and fabricating the TFT array on the substrate,
2. fabricating the color filter film 6,
3. fabricating the flat layer 5 on the color filter film 6,
4. fabricating the single-layer optical resonance layer 4 on the flat layer 5 of the corresponding to the region of a G sub-pixel, and fabricating the filling layer 4′ in the other regions,
5. fabricating the transparent electrode 3 on the optical resonance layer 4 and the filling layer 4′,
6. fabricating the white light OLED 2 and the reflection electrode 1 on the transparent electrode 3, and
7. packaging to complete the fabricating of the OLED device of the first embodiment.

### The Second Embodiment

As shown in FIG. 2, the difference between this embodiment and the first embodiment is that the optical resonance layer 4 is a double-layer medium structure. That is, the optical resonance layer 4 of the second embodiment comprises a first medium layer 42 and a second medium layer 41.

The method for fabricating the OLED device of the embodiment is as follows:
1. cleaning the substrate, and fabricating the TFT array on the substrate,
2. fabricating the color filter film 6,
3. fabricating the flat layer 5 on the color filter film 6,
4. fabricating the first medium layer 42 on the flat layer 5 of the corresponding to the region of a G sub-pixel, and fabricating the second medium layer 41 on the first medium layer 42, to complete the fabricating of the optical resonance layer 4 with a double medium layer structure, and fabricating the filling layer 4′ in the other regions,
5. fabricating the transparent electrode 3 on the optical resonance layer 4 and the filling layer 4′,
6. fabricating the white light OLED 2 and the reflection electrode 1 on the transparent electrode 3, and
7. packaging to complete the fabricating of the OLED device of the second embodiment.

### The Third Embodiment

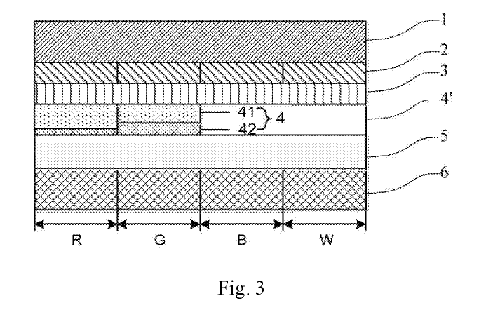

As shown in FIG. 3, the difference between this embodiment and the first embodiment is that the optical resonance layer 4 is also arranged in the region of the R sub-pixel, besides the region of the G sub-pixel, and the optical resonance layers 4 in the two regions are both double-layer medium structures. That is, the optical resonance layers 4 of the third embodiment comprise a first medium layer 42 and a second medium layer 41. Further, the material of the optical resonance layer in the G sub-pixel region is different from that of the optical resonance layer in the R sub-pixel region.

The method for fabricating the OLED device of the embodiment is as follows:
1. cleaning the substrate, and fabricating the TFT array on the substrate,
2. fabricating the color filter film 6,
3. fabricating the flat layer 5 on the color filter film 6,
4. fabricating the first medium layers 42 on the flat layer 5 of the corresponding to the region of a G sub-pixel and the R sub-pixel, respectively, and fabricating the second medium layers 41 on the first medium layers 42, to complete the fabricating of the optical resonance layers 4 with a double medium layer structure, wherein the thicknesses of each medium layer of the resonance layers corresponding to the R sub-pixel and the G sub-pixel are respectively the thickness of the interference enhancement of filtered light by the R sub-pixel and the G sub-pixel, and fabricating the filling layer 4′ in the other regions,
5. fabricating the transparent electrode 3 on the optical resonance layers 4 and the filling layer 4′,
6. fabricating the white light OLED 2 and the reflection electrode 1 on the transparent electrode 3, and
7. packaging to complete the fabricating of the OLED device of the third embodiment.

The OLED device of the present invention enhances the extraction of the monochromatic lights, reduces the power consumption, improves the color quality, reduces the requirements on the CF, and meanwhile has no need to evaporation dispose a precision mask plate.

The material of the first medium layer may choose ITO, ZTO, TiO₂, SiNₓ, NiO, MgO, SnO₃, ZnO, ZnS or ZnSe. The material of the second medium layer may choose ITO, SiOₓ, Al₂O₃ or ZTO.

The advantageous effects of the present invention will be explained with the experimental data, and the experimental method adopts the commonly used method for measuring light efficiency in this field.

### COMPARATIVE EXAMPLE

there is no medium layer material. The experimental results show that the green light efficiency is 18.09 cd/A, CIE (0.26, 0.63), and the red light efficiency is 12.96 cd/A, CIE (0.65, 0.34).

### Example 1 (its Structure is as Shown in FIG. 1)

The material of the first medium layer in the green light region is SiNₓ, and the thickness is 10 nm. The thickness of the second medium layer is 0 nm, that is, a single medium layer structure is adopted only comprising the first medium layer. The experimental results show that the green light efficiency is 23.54 cd/A, CIE (0.24, 0.65). The efficiency and chromaticity of green light have been improved, and the other regions are the same as the comparative example.

### Example 2 (its Structure is as Shown in FIG. 1)

The material of the first medium layer in the green light region is SiNₓ, and the thickness is 70 nm. The thickness of the second medium layer is 0 nm, that is, a single medium layer structure is adopted only comprising the first medium layer. The experimental results show that the green light efficiency is 25.54 cd/A, CIE (0.23, 0.65). The efficiency and chromaticity of green light have been improved, and the other regions are the same as the comparative example.

### Example 3 (its Structure is as Shown in FIG. 1)

The material of the first medium layer in the green light region is SiNₓ, and the thickness is 150 nm. The thickness of the second medium layer is 0 nm, that is, a single medium layer structure is adopted only comprising the first medium layer. The experimental results show that the green light efficiency is 28.54 cd/A, CIE (0.23, 0.64). The efficiency and chromaticity of green light have been improved, and the other regions are the same as the comparative example.

### Example 4 (its Structure is as Shown in FIG. 2)

The material of the first medium layer in the green light region is SiNₓ, and the thickness is 50 nm. The material of the second medium layer is SiOₓ, and the thickness is 10 nm. The experimental results show that the green light efficiency is 25.54 cd/A, CIE (0.23, 0.64). The efficiency and chromaticity of green light have been improved, and the other regions are the same as the comparative example.

### Example 5 (its Structure is as Shown in FIG. 2)

The material of the first medium layer in the green light region is SiNₓ, and the thickness is 50 nm. The material of the second medium layer is SiOₓ, and the thickness is 120 nm. The experimental results show that the green light efficiency is 34.9 cd/A, CIE (0.21, 0.69). The efficiency and chromaticity of green light have been improved, and the other regions are the same as the comparative example.

### Example 6 (its Structure is as Shown in FIG. 3)

The material of the first medium layer in the green light region is SiNₓ, and the thickness is 50 nm. The material of the second medium layer is SiOₓ, and the thickness is 10 nm. The experimental results show that the green light efficiency is 25.54 cd/A, CIE (0.23, 0.64). The material of the first medium layer in the red light region is SiNₓ, and the thickness is 50 nm. The material of the second medium layer is SiOₓ, and the thickness is 160 nm. The experimental results show that the red light efficiency is 16.16 cd/A, CIE (0.66, 0.34). The efficiency and chromaticity of green light and red light have both been improved, and the other regions are the same as the comparative example.

### Example 7 (its Structure is as Shown in FIG. 2)

The material of the first medium layer in the green light region is SiNₓ, and the thickness is 50 nm. The material of the second medium layer is SiOₓ, and the thickness is 300 nm. The experimental results show that the green light efficiency is 27.3 cd/A, CIE (0.25, 0.67). The efficiency and chromaticity of green light have been improved, and the other regions are the same as the comparative example.

The above examples are merely preferable examples, in order to fully explain the present invention, and the scope of the present invention is not limited thereto. All the equivalent substitutions and variations made by those skilled in the art on the basis of the present invention will fall within the scope of the present invention. The protection scope of the present invention is defined in the claims.

What is claimed is:

1. An OLED device with an optical resonance layer, comprising: a white light OLED and a color filter film, so as to form an R sub-pixel, a G sub-pixel, a B sub-pixel and a W sub-pixel, characterized in that: an optical resonance layer is disposed at least in a region corresponding to the G sub-pixel between the white light OLED and the color filter film.

2. The OLED device with an optical resonance layer as claimed in claim 1, characterized in that: the optical resonance layer is a composite medium layer which at least comprises a first medium layer and a second medium layer, wherein the first medium layer is close to the color filter film, the second medium layer is located on the first medium layer, and a refractive index of the first medium layer is higher than that of the second medium layer.

3. The OLED device with an optical resonance layer as claimed in claim 2, characterized in that: the refractive index of the second medium layer is 1-1.6.

4. The OLED device with an optical resonance layer as claimed in claim 2 or 3, characterized in that: the refractive index of the first medium layer is at least 0.2 higher than the refractive index of the second medium layer.

5. The OLED device with an optical resonance layer as claimed in claim 1, characterized in that: a thickness of the optical resonance layer enables optical paths from a reflection electrode to each of interfaces of the medium layers to meet an interference enhancement formula: L=(2n+1)λ/4, wherein: L is the optical path from the reflection electrode to one of the interfaces of the medium layers, n is a natural number, and λ is a central wavelength of filtered light.

6. The OLED device with an optical resonance layer as claimed in claim 2, characterized in that: a thickness of the first medium layer is 10-150 nm, and a thickness of the second medium layer is 0-300 nm.

7. The OLED device with an optical resonance layer as claimed in claim 1, characterized in that: the optical resonance layer is disposed in one selected from, or in any combination of regions corresponding to the R sub-pixel, the B sub-pixel and the W sub-pixel between the white light OLED and the color filter film.

8. A display device comprising the OLED device with an optical resonance layer as claimed in any one of claims 1-7.

9. A method for fabricating an OLED device with an optical resonance layer, characterized by, comprising the steps of:
cleaning a substrate, and fabricating a TFT array on the substrate,
fabricating a color filter film,
fabricating a flat layer on the color filter film,
fabricating the optical resonance layer on the flat layer of the corresponding to the region of a G sub-pixel,
fabricating a transparent electrode on the optical resonance layer,
fabricating a white light OLED device, and
packaging to complete the fabricating of the display device.

10. The method for fabricating an OLED device with an optical resonance layer as claimed in claim 9, characterized in that: the step of fabricating the optical resonance layer in a region corresponding to a G sub-pixel comprises:
fabricating a first medium layer with a thickness of 10-150 nm, and
fabricating a second medium layer with a thickness of 0-300 nm on the first medium layer.
